(19) United States
(12) Patent Application Publication
(10) Pub. No.: US 2023/0112048 A1
(43) Pub. Date: Apr. 13, 2023

(54) CHEMICAL LIQUID AND TREATMENT METHOD

(71) Applicant: FUJIFILM Corporation, Tokyo (JP)

(72) Inventors: Atsushi MIZUTANI, Haibara-gun (JP); Yuta SHIGENOI, Haibara-gun (JP)

(73) Assignee: FUJIFILM Corporation, Tokyo (JP)

(21) Appl. No.: 17/895,534

(22) Filed: Aug. 25, 2022

(30) Foreign Application Priority Data
Sep. 24, 2021 (JP) 2021-155148

(51) Int. Cl. C09K 13/06; H01L 21/311

(52) U.S. Cl. CPC C09K 13/06; H01L 21/31111

(57) ABSTRACT

A chemical liquid contains phosphoric acid or a salt thereof, a polar aprotic solvent, water, and a compound that has a carboxy group and does not have a hydroxyl group or a salt of the compound, in which a content of the phosphoric acid or a salt thereof is 5.0% by mass or less with respect to a total mass of the chemical liquid, a content of the polar aprotic solvent is 50.0% by mass or more with respect to the total mass of the chemical liquid, and a content of the water is 2.0% by mass or more and less than 50.0% by mass with respect to the total mass of the chemical liquid.

### CROSS-REFERENCE TO RELATED APPLICATIONS

The present application claims priority under 35 U.S.C. §119 to Japanese Patent Application No. 2021-155148 filed on Sep. 24, 2021. Each of the above application is hereby expressly incorporated by reference, in its entirety, into the present application.

### BACKGROUND OF THE INVENTION

### 1. Field of the Invention

The present invention relates to a chemical liquid and a treatment method.

### 2. Description of the Related Art

As the miniaturization of semiconductor products progresses, there is an increasing demand for performing a step of removing unnecessary transition metal-containing substances on a substrate in a semiconductor product manufacturing process with high efficiency and high accuracy.

For example, as a step of removing an unnecessary Al-containing metal oxide (hereinafter, also called “Al oxide”) on a substrate, for example, a method is widely known in which etching or removal of foreign substances attached to a solid surface is performed using a chemical liquid dissolving the unnecessary Al oxide.

For example, JP2008-541426A discloses “a composition for cleaning a substrate of microelectronics that contains (a) at least one kind of water-soluble or water-miscible organic solvent, (b) at least one kind of inorganic phosphorus-containing acid not being neutralized, and (c) water, and does not contain an organic amine, hydroxylamine, and a strong base that neutralize inorganic phosphorus-containing acid components”.

### SUMMARY OF THE INVENTION

Examples of performances required for the aforementioned chemical liquid include exhibiting an excellent etching ability to the unnecessary Al oxide, being capable of suppressing the etching ability from being exhibited to a metal oxide containing necessary Ga (hereinafter, also called “Ga oxide”) that is not a removal target, and having excellent etching selectivity of the Al oxide to the Ga oxide.

In order to dissolve the unnecessary Al oxide, a method of extending the contact time between the chemical liquid and the object to be treated may also be used. In this case, the extension of contact time with the chemical liquid often causes the necessary Ga oxide to be dissolved as well in addition to the unnecessary Al oxide. Therefore, the chemical liquid is required to have especially higher etching selectivity of the Al oxide to the Ga oxide.

The etching selectivity of the Al oxide to the Ga oxide means being able to selectively etch the unnecessary Al oxide in a case where the object to be treated is treated using the chemical liquid. More specifically, the etching selectivity of the Al oxide to the Ga oxide means that in a case where the Al oxide is removed, the ratio of an etching rate of the Al oxide as a removal target to an etching rate of the Ga oxide not being a removal target (etching rate of Al oxide/etching rate of Ga oxide) is high.

As a result of investigating the chemical liquid described in JP2008-541426A and the like, the inventors of the present invention have found that the chemical liquid is poor in at least one of the performances including the Al oxide etching ability, the inhibition of the Ga oxide etching ability, and the etching selectivity of the Al oxide to the Ga oxide.

Therefore, an object of the present invention is to provide a chemical liquid that has an excellent Al oxide etching ability, excellently inhibits a Ga oxide etching ability, and has excellent etching selectivity of an Al oxide to a Ga oxide.

Another object of the present invention is to provide a treatment method using the aforementioned chemical liquid.

In order to achieve the above objects, the inventors of the present invention conducted intensive studies. As a result, the inventors have found that the objects can be achieved by the following constitutions.
[1] A chemical liquid containing phosphoric acid or a salt thereof, a polar aprotic solvent, water, and a compound that has a carboxy group and does not have a hydroxyl group or a salt of the compound,
   in which a content of the phosphoric acid or a salt thereof is 5.0% by mass or less with respect to a total mass of the chemical liquid,
   a content of the polar aprotic solvent is 50.0% by mass or more with respect to the total mass of the chemical liquid, and
   a content of the water is 2.0% by mass or more and less than 50.0% by mass with respect to the total mass of the chemical liquid.
The chemical liquid described in [1], in which the content of the phosphoric acid or a salt thereof is 3.0% by mass or less with respect to the total mass of the chemical liquid.
The chemical liquid described in [1] or [2], in which the polar aprotic solvent includes at least one solvent selected from the group consisting of sulfolane, dimethyl sulfoxide, and an ether-based solvent.
The chemical liquid described in any one of [1] to [3], in which the polar aprotic solvent includes sulfolane.
The chemical liquid described in any one of [1] to [4], in which a mass ratio of the content of the polar aprotic solvent to the content of the phosphoric acid or a salt thereof is more than 40.
The chemical liquid described in any one of [1] to [5], in which a mass ratio of the content of the polar aprotic solvent to the content of the phosphoric acid or a salt thereof is more than 80.
The chemical liquid described in any one of [1] to [6], in which the content of the water is 2.0% to 30.0% by mass with respect to the total mass of the chemical liquid.
The chemical liquid described in any one of [1] to [7], in which the content of the water is 2.0% to 15.0% by mass with respect to the total mass of the chemical liquid.
The chemical liquid described in any one of [1] to [8], in which the content of the water is 2.0% to 10.0% by mass with respect to the total mass of the chemical liquid.
The chemical liquid described in any one of [1] to [9], in which the compound that has a carboxy group and does not have a hydroxyl group or a salt of the compound includes at least one compound selected from the group consisting of a compound represented by Formula (C1) which will be described later and a compound having a repeating unit represented by Formula (C2) which will be described later.
The chemical liquid described in any one of [1] to [10], in which the compound that has a carboxy group and does not have a hydroxyl group or a salt of the compound includes at least one compound selected from the group consisting of acetic acid, malonic acid, succinic acid, glutaric acid, octanoic acid, 2-ethylhexanoic acid, poly(meth)acrylic acid, and a salt of these.
The chemical liquid described in any one of [1] to [11], in which the chemical liquid substantially does not contain a fluoride.
The chemical liquid described in any one of [1] to [12], in which the chemical liquid substantially does not contain hydrogen peroxide.
The chemical liquid described in any one of [1] to [13], in which the chemical liquid substantially does not contain abrasive particles.
The chemical liquid described in any one of [1] to [14], in which a pH of the chemical liquid is 2 or less.
The chemical liquid described in any one of [1] to [15], in which the chemical liquid is used for an object to be treated that includes an Al-containing metal oxide and a Ga-containing metal oxide.
The chemical liquid described in any one of [1] to [16], in which the chemical liquid is used as an etchant.
A treatment method having a step of bringing an object to be treated including an Al-containing metal oxide and a Ga-containing metal oxide into contact with the chemical liquid described in any one of [1] to [17].
The treatment method described in [18], in which a temperature of the chemical liquid is 40° C. to 80° C.

According to the present invention, it is possible to provide a chemical liquid that has an excellent Al oxide etching ability, excellently inhibits a Ga oxide etching ability, and has excellent etching selectivity of an Al oxide to a Ga oxide. Furthermore, according to the present invention, it is possible to provide a substrate treatment method using the chemical liquid.

### DESCRIPTION OF THE PREFERRED EMBODIMENTS

Hereinafter, the present invention will be specifically described.

The following constituents will be described based on typical embodiments of the present invention in some cases, but the present invention is not limited to the embodiments.

The meaning of each description in the present specification is as below.

A range of numerical values described using “to” means a range including the numerical values listed before and after “to” as the lower limit and the upper limit.

“Preparation” includes the preparation of a specific material by synthesis, mixing, or the like and the preparation of a predetermined substance by purchase or the like.

In a case where there are two or more kinds of components corresponding to a certain component, unless otherwise specified, “content” of such a component means the total content of the two or more kinds of components.

“Main component” means a component of the highest content.

“ppm” means parts-per-million (10⁻⁶). “ppt” means parts-per-trillion (10⁻¹²).

“Radiation” means the bright line spectrum of a mercury lamp, far ultraviolet rays represented by an excimer laser, extreme ultraviolet rays (EUV light), X-rays, or electron beams.

“Light” means an actinic ray or radiation.

Unless otherwise specified, “exposure” includes exposure to a mercury lamp, far ultraviolet rays represented by an excimer laser, X-rays, or EUV light and exposure to particle beams such as electron beams or ion beams.

“(Meth)acrylic acid” is a concept that includes both the acrylic acid and methacrylic acid.

Regarding the description of a compound, unless otherwise specified, the compound may include structural isomers (compounds having the same number of atoms but different structures), optical isomers, and isotopes. Furthermore, the compound may include one kind of structural isomer, optical isomer, and isotope or include two or more kinds of structural isomers, optical isomers, and isotopes.

Regarding the bonding direction of a divalent group (for example, -COO-), in a case where Y in a compound represented by “X-Y-Z” is -COO-, unless otherwise specified, the compound may be either “X-O-CO-Z” or “X-CO-O-Z”.

### Chemical Liquid

The chemical liquid is a chemical liquid containing phosphoric acid or a salt thereof, a polar aprotic solvent, water, and a compound that has a carboxy group and does not have a hydroxyl group or a salt of the compound,
in which a content of the phosphoric acid or a salt thereof is 5.0% by mass or less with respect to a total mass of the chemical liquid,
a content of the polar aprotic solvent is 50.0% by mass or more with respect to the total mass of the chemical liquid, and
a content of the water is 2.0% by mass or more and less than 50.0% by mass with respect to the total mass of the chemical liquid.

The mechanism through which the chemical liquid having the above composition achieves the above objects is unclear. According to the inventors of the present invention, the mechanism is considered to be as below.

In the chemical liquid, the phosphoric acid or a salt thereof has a function of improving the Al oxide etching ability, and the polar aprotic solvent and the specific compound have a function of inhibiting the Ga oxide etching ability. Presumably, as a result of setting the quantity of each of these components to a predetermined amount to adjust the Al oxide etching ability and the Ga oxide etching ability, an excellent Al oxide etching ability, excellent properties of inhibiting a Ga oxide etching ability, and excellent etching selectivity of an Al oxide to a Ga oxide may be obtained.

Hereinafter, obtaining at least one effect among the excellent Al oxide etching ability, the excellent properties of inhibiting a Ga oxide etching ability, and the excellent etching selectivity of an Al oxide to a Ga oxide will be also described as “bring about the excellent effect of the present invention”.

### Various Components

Hereinafter, the components that can be contained in the chemical liquid will be specifically described.

### Phosphoric Acid or Salt Thereof

The chemical liquid contains phosphoric acid or a salt thereof.

The content of the phosphoric acid or a salt thereof with respect to the total mass of the chemical liquid is 5.0% by mass or less, preferably 3.0% by mass or less, and more preferably 1.0% by mass or less. The lower limit of the content of the phosphoric acid or a salt thereof with respect to the total mass of the chemical liquid is preferably more than 0% by mass, more preferably 0.1% by mass or more, and even more preferably 0.5% by mass or more.

Examples of the method of measuring the content of the phosphoric acid or a salt thereof include known measuring methods such as ion chromatography and capillary electrophoresis.

Examples of the phosphoric acid include orthophosphoric acid (H₃PO₄), diphosphoric acid, metaphosphoric acid, and polyphosphoric acid. Among these, orthophosphoric acid is preferable.

Examples of the salt of the phosphoric acid include metal salts which are preferably salts of alkali metal such as sodium and potassium, salts of alkaline earth metals such as calcium and magnesium, and aluminum salts.

The phosphoric acid may form salts with various other components contained in the chemical liquid.

One kind of phosphoric acid or a salt thereof may be used alone, or two or more kinds of phosphoric acids or salts thereof may be used.

### Polar Aprotic Solvent

The chemical liquid may contain a polar aprotic solvent.

The content of the polar aprotic solvent with respect to the total mass of the chemical liquid is 50.0% by mass or more, preferably 60.0% by mass or more, more preferably 70.0% by mass or more, and even more preferably 75.0% by mass or more. The upper limit of the content of the polar aprotic solvent with respect to the total mass of the chemical liquid is preferably 95.0% by mass or less, and more preferably 90.0% by mass or less.

Examples of the method of measuring the content of the polar aprotic solvent include known measuring methods such as gas chromatography and liquid chromatography.

Examples of the polar aprotic solvent include a sulfolane-based solvent, a sulfoxide-based solvent, an ether-based solvent, and an amide-based solvent.

Examples of the sulfolane-based solvent include sulfolane, methyl sulfolane, and dimethyl sulfolane. Among these, sulfolane is preferable.

Examples of the sulfoxide-based solvent include dimethyl sulfoxide.

Examples of the ether-based solvent include glycol ether, glycol diether, and cyclic ether.

As the glycol ether, (mono/di/tri/poly)ethylene glycol alkyl ether, ethylene glycol aryl ether, (mono/di/tri/poly)propylene glycol alkyl ether, or propylene glycol aryl ether is preferable.

Examples of the (mono/di/tri/poly)ethylene glycol alkyl ether include ethylene glycol monomethyl ether, ethylene glycol monoethyl ether, ethylene glycol monopropyl ether, diethylene glycol monobutyl ether, diethylene glycol monomethyl ether, triethylene glycol monomethyl ether, triethylene glycol monoethyl ether, and polyethylene glycol monomethyl ether.

“(Mono/di/tri/poly)ethylene glycol” is a concept that includes monoethylene glycol, diethylene glycol, triethylene glycol, and polyethylene glycol.

Examples of the ethylene glycol aryl ether include ethylene glycol monophenyl ether, ethylene glycol monobenzyl ether, and diethylene glycol monobenzyl ether.

Examples of the (mono/di/tri/poly)propylene glycol alkyl ether include propylene glycol monomethyl ether, propylene glycol monoethyl ether, propylene glycol monopropyl ether, dipropylene glycol monobutyl ether, dipropylene glycol monomethyl ether, tripropylene glycol monomethyl ether, tripropylene glycol monoethyl ether, and polypropylene glycol monomethyl ether.

“(Mono/di/tri/poly)propylene glycol” is a concept that includes monopropylene glycol, dipropylene glycol, tripropylene glycol, and polypropylene glycol.

Examples of the propylene glycol aryl ether include propylene glycol monophenyl ether, propylene glycol monobenzyl ether, and dipropylene glycol monobenzyl ether.

As the glycol diether, (mono/di/tri/poly)ethylene glycol dialkyl ether or (mono/di/tri/poly)propylene glycol dialkyl ether is preferable.

Examples of the (mono/di/tri/poly)ethylene glycol dialkyl ether include tetraethylene glycol dimethyl ether, diethylene glycol diethyl ether, diethylene glycol butyl methyl ether, diethylene glycol dibutyl ether, triethylene glycol butyl methyl ether, diethylene glycol ethyl methyl ether, diethylene glycol dimethyl ether, ethylene glycol dimethyl ether, polyethylene glycol dimethyl ether, and triethylene glycol dimethyl ether.

As the (mono/di/tri/poly)ethylene glycol dialkyl ether, tetraethylene glycol dimethyl ether, diethylene glycol diethyl ether, or diethylene glycol butyl methyl ether is preferable.

Examples of the (mono/di/tri/poly)propylene glycol dialkyl ether include tetrapropylene glycol dimethyl ether, dipropylene glycol diethyl ether, dipropylene glycol butyl methyl ether, dipropylene glycol dibutyl ether, tripropylene glycol butyl methyl ether, dipropylene glycol ethyl methyl ether, dipropylene glycol dimethyl ether, propylene glycol dimethyl ether, polypropylene glycol dimethyl ether, and tripropylene glycol dimethyl ether.

As the (mono/di/tri/poly)propylene glycol dialkyl ether, tetrapropylene glycol dimethyl ether, dipropylene glycol diethyl ether, or dipropylene glycol butyl methyl ether is preferable.

Examples of the cyclic ether include 1,4-dioxane and 1,3-dioxolane.

Examples of the amide-based solvent include N,N-dimethylformamide, 1-methyl-2-pyrrolidone, 2-pyrrolidinone, 1,3-dimethyl-2-imidazolidinone, formamide, N-methylformamide, acetamide, N-methylacetamide, N,N-dimethylacetamide, N-methylpropanamide, and hexamethylphosphoric triamide.

The polar aprotic solvent preferably includes at least one solvent selected from the group consisting of a sulfolane-based solvent, a sulfoxide-based solvent, and an ether-based solvent, more preferably includes at least one solvent selected from the group consisting of sulfolane, dimethyl sulfoxide, and an ether-based solvent, even more preferably includes at least one solvent selected from the group consisting of sulfolane, dimethyl sulfoxide, and glycol diether, and particularly preferably includes sulfolane.

One kind of polar aprotic solvent may be used alone, or two or more kinds of polar aprotic solvents may be used.

The mass ratio of the content of the polar aprotic solvent to the content of the phosphoric acid or a salt thereof (content of polar aprotic solvent/content of phosphoric acid or salt thereof) is preferably more than 40, and more preferably more than 80. The upper limit of the mass ratio is not particularly limited, but is 100 or less in many cases.

### Water

The chemical liquid contains water.

The content of the water with respect to the total mass of the chemical liquid is 2% by mass or more and less than 50% by mass, preferably 2% to 30% by mass, more preferably 2% to 15% by mass, and even more preferably 2% to 10% by mass.

Examples of the method of measuring the content of the water include known measuring methods such as the Karl Fischer method.

Examples of the water include ultrapure water used for manufacturing semiconductor devices.

The water is preferably water in which the content of inorganic anions, metal ions, or the like is reduced, more preferably water in which the concentration of ions derived from metal atoms selected from Fe, Co, Na, K, Ca, Cu, Mg, Mn, Li, Al, Cr, Ni, and Zn is reduced, and even more preferably water in which the content of the above metal atoms is adjusted in the order of ppt by mass or less (for example, the content of the metals is less than 0.001 mass ppt or the like) in a case where the water is used for preparing the chemical liquid.

Examples of the method of adjusting the content of the above metal atoms include the method described in paragraphs “0074” to “0084” of JP2011-110515A and the methods described in JP2007-254168A. As the adjusting method, purification or distillation purification using a filtration membrane or an ion-exchange membrane is preferable.

As the water used in the embodiment of the present invention, the water obtained as above is preferable.

It is preferable that the water be also used for cleaning the container that will be described later. It is also preferable that the water be also in the manufacturing process of the chemical liquid, the measurement of components of the chemical liquid, and the measurement for evaluating the chemical liquid.

### Specific Compound

The chemical liquid contains a specific compound.

The specific compound is a compound that has a carboxy group and does not have a hydroxyl group or a salt of the compound.

The specific compound may have other functional groups as long as the specific compound has a carboxy group and does not have a hydroxyl group. It is more preferable that the specific compound have only a carboxy group as a functional group.

It is also preferable that the specific compound do not have any of a hydroxyl group, a primary amino group, a secondary amino group, and a tertiary amino group.

The number of carboxy groups contained in the specific compound is 1 or more, preferably 1 to 5, more preferably 1 to 3, and even more preferably 2.

The specific compound may be a salt. It is preferable that the specific compound be not a salt.

Examples of the salt of the specific compound include metal salts which are preferably salts of alkali metals such as sodium and potassium and salts of alkaline earth metals such as calcium and magnesium. Furthermore, the specific compound may form salts with various other components contained in the chemical liquid.

The specific compound preferably includes at least one compound selected from the group consisting of a compound represented by Formula (C1) and a compound having a repeating unit represented by Formula (C2), and more preferably includes the compound represented by Formula (C1).

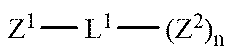

In Formula (C1), Z¹ represents a hydrocarbon group or a carboxy group or a salt thereof. L¹ represents a single bond or an (n + 1)-valent hydrocarbon group. Z² represents a carboxy group or a salt thereof. n represents an integer of 1 to 5. Here, in a case where L¹ represents a single bond, n represents 1.

Z¹ represents a hydrocarbon group or a carboxy group or a salt thereof.

As the hydrocarbon group, an alkyl group is preferable.

The alkyl group may be linear, branched, or cyclic.

The number of carbon atoms in the alkyl group is preferably 1 to 20, more preferably 1 to 10, and even more preferably 1 to 3.

The salt of the carboxy group is -COO⁻M⁺. M⁺ is a monovalent cation other than H⁺. As M⁺, a monovalent metal cation or an ammonium cation is preferable, and cations of alkali metals such as sodium and potassium are more preferable.

As Z¹, a carboxy group is preferable.

L¹ represents a single bond or an (n + 1)-valent hydrocarbon group.

As the (n + 1)-valent hydrocarbon group, a group formed by the removal of (n + 1) pieces of hydrogen atoms from hydrocarbon is preferable.

The aforementioned hydrocarbon may be linear, branched, or cyclic.

The number of carbon atoms in the hydrocarbon is preferably 1 to 20, more preferably 1 to 10, and even more preferably 1 to 3.

Examples of the hydrocarbon include an aliphatic hydrocarbon having 1 to 20 carbon atoms (for example, an alkylene group or the like), an aliphatic ring having 3 to 20 carbon atoms, and an aromatic ring having 3 to 20 carbon atoms. The hydrocarbon may be combined with at least one divalent linking group selected from the group consisting of -O-, -S-, -CO-, -NR^{N}- (R^{N} represents a hydrogen atom or a substituent) and -SO₂-.

Z² represents a carboxy group or a salt thereof.

As Z², a carboxy group is preferable.

The salt of the carboxy group has the same definition as the salt of the carboxy group represented by Z¹, and the suitable aspects thereof are also the same.

n represents an integer of 1 to 5. Here, in a case where L¹ represents a single bond, n represents 1.

n is preferably an integer of 1 to 3, and more preferably 1.

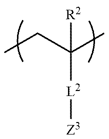

In formula (C2), R² represents a hydrogen atom, a methyl group, or a carboxy group or a salt thereof. L² represents a single bond or a divalent linking group. Z³ represents a carboxy group or a salt thereof.

R² represents a hydrogen atom, a methyl group, or a carboxy group or a salt thereof.

The salt of the carboxy group has the same definition as the salt of the carboxy group represented by Z¹, and the suitable aspects thereof are also the same.

As R², a hydrogen atom or a carboxy group is preferable, and a carboxy group is more preferable.

L² represents a single bond or a divalent linking group.

Examples of the divalent linking group represented by L² include a divalent linking group represented by L¹. As the divalent linking group, an alkylene group is preferable.

The alkylene group may be linear, branched, or cyclic, and is preferably linear.

The number of carbon atoms in the alkylene group is preferably 1 to 20, more preferably 1 to 10, and even more preferably 1 to 3.

Z³ represents a carboxy group or a salt thereof.

As Z³, a carboxy group is preferable.

The salt of the carboxy group has the same definition as the salt of the carboxy group represented by Z¹, and the suitable aspects thereof are also the same.

Examples of the specific compound include a monocarboxylic acid having no hydroxyl group, a dicarboxylic acid having no hydroxyl group, a polycarboxylic acid having no hydroxyl group, and a salt of these.

Examples of monocarboxylic acid having no hydroxyl group and a salt thereof include formic acid, acetic acid, propanoic acid, butanoic acid, pentanoic acid, hexanoic acid, heptanoic acid, octanoic acid, nonanoic acid, decanoic acid, 2-ethylhexanoic acid, and a salt of these.

Examples of the dicarboxylic acid having no hydroxyl group and a salt thereof include oxalic acid, malonic acid, succinic acid, glutaric acid, adipic acid, fumaric acid, maleic acid, pimelic acid, suberic acid, azelaic acid, sebacic acid, and a salt of these.

Examples of the polycarboxylic acid having no hydroxyl group and a salt thereof include trimellitic acid, poly(meth)acrylic acid, polymaleic acid, polyitaconic acid, and a salt of these.

The above salts are as described above.

The specific compound preferably includes at least one compound selected from the group consisting of acetic acid, malonic acid, succinic acid, glutaric acid, octanoic acid, 2-ethylhexanoic acid, poly(meth)acrylic acid, and a salt of these, more preferably includes at least one compound selected from the group consisting of malonic acid, poly(meth)acrylic acid, and a salt of these, even more preferably includes at least one compound selected from the group consisting of malonic acid and a salt thereof, and particularly preferably includes malonic acid.

The specific compound may be a low-molecular-weight compound or a high-molecular-weight compound.

In a case where the specific compound is a low-molecular-weight compound, the molecular weight of the specific compound is preferably 50 to 500, and more preferably 50 to 200.

In a case where the specific compound is a high-molecular-weight compound, the molecular weight of the specific compound is preferably 1,000 to 100,000, and more preferably 2,000 to 30,000.

One kind of specific compound may be used alone, or two or more kinds of specific compounds may be used.

The content of the specific compound with respect to the total mass of the chemical liquid is preferably 0.01% to 45.0% by mass, more preferably 5.0% to 45.0% by mass, and even more preferably 7.0% to 45.0% by mass.

### Fluoride

In view of bring about the excellent effect of the present invention, it is preferable that the chemical liquid substantially do not contain a fluoride.

Specifically, “substantially do not contain a fluoride” means that the content of a fluoride is 1% by mass or less with respect to the total mass of the chemical liquid. The content of a fluoride is preferably 0.1 % by mass or less, and more preferably 0.01 % by mass or less. The lower limit of the content of a fluoride is preferably 0% by mass or more with respect to the total mass of the chemical liquid.

Examples of the fluoride include hydrofluoric acid, ammonium fluoride, tetramethylammonium fluoride, hexafluorosilicic acid, hexafluorophosphoric acid, and tetrafluoroboric acid.

### Hydrogen Peroxide

It is preferable that the chemical liquid substantially do not contain hydrogen peroxide.

Specifically, “substantially do not contain hydrogen peroxide” means that the content of hydrogen peroxide is 1% by mass or less with respect to the total mass of the chemical liquid. The content of hydrogen peroxide is preferably 0.1% by mass or less, and more preferably 0.01% by mass or less. The lower limit of the content of hydrogen peroxide is preferably 0% by mass or more with respect to the total mass of the chemical liquid.

### Abrasive Particles

It is preferable that the chemical liquid substantially do not contain abrasive particles.

Specifically, “substantially do not contain abrasive particles” means that the content of abrasive particles is 1,000 ppm by mass or less with respect to the total mass of the chemical liquid. The content of abrasive particles is preferably 500 ppm by mass or less, and more preferably 100 ppm by mass or less. The lower limit of the content of abrasive particles is preferably 0% by mass or more with respect to the total mass of the chemical liquid.

Examples of abrasive particles include the abrasive particles such as silicon oxide contained in a slurry for chemical mechanical polishing and those described in paragraphs “0194” to “0197” of WO2021/131451A.

Examples of the method of measuring the content of abrasive particles include a method of measuring the content of abrasive particles in a liquid phase by using a commercially available measuring device used in a light scattering-type liquid-borne particle measuring method employing a laser as a light source.

Examples of the method of adjusting the content of the abrasive particles include known methods such as a filtering treatment.

### Optional Components

The chemical liquid may further contain an optional component in addition to the above components.

One kind of optional component may be used alone, or two or more kinds of optional components may be used.

### Basic Compound

The basic compound is a compound that exhibits alkalinity (pH higher than 7.0) in an aqueous solution.

The basic compound is a compound different from the various components described above.

Examples of the basic compound include an organic base, an inorganic base, and a salt of these.

Examples of the organic base include ammonium hydroxide (NH₄OH), a quaternary ammonium salt, an amine compound and a salt thereof, a nitro compound, a nitroso compound, an oxime compound, a ketoxime compound, an aldoxime compound, a lactam compound, and an isocyanide compound.

The quaternary ammonium salt is a quaternary ammonium cation-containing salt formed by the substitution of a nitrogen atom with four hydrocarbon groups.

Examples of the quaternary ammonium salt include a hydroxide, a fluoride, a bromide, an iodide, an acetate, and a carbonate.

Examples of the quaternary ammonium salt include tetramethylammonium hydroxide (TMAH), tetraethylammonium hydroxide (TEAH), tetrapropylammonium hydroxide (TPAH), tetrabutylammonium hydroxide (TBAH), and tetra(hydroxyethyl)ammonium hydroxide. Among these, TMAH, TEAH, TPAH, or TBAH is more preferable.

The amine compound is a compound that has an amino group in the molecule.

Examples of the amine compound include a primary amine having a primary amino group (-NH₂) in the molecule, a secondary amine having a secondary amino group (>NH) in the molecule, a tertiary amine having a tertiary amino group (>N-) in the molecule, and a salt of these.

Examples of the salt of the amine compound include an inorganic salt formed by the bonding of at least one non-metal selected from the group consisting of Cl, S, N, and P to hydrogen. As such a salt, a hydrochloride, a sulfate, or a nitrate is preferable.

The amine compound is preferably a water-soluble amine capable of dissolving in an amount of 50 g or more in 1 L of water.

Examples of the amine compound include an alicyclic amine compound, an aliphatic amine, an alkanolamine, and a hydroxyamine compound.

Among amine compounds, a compound having a ring structure in the molecule is an alicyclic amine compound.

Examples of the alicyclic amine compound include 1,8-diazabicyclo[5.4.0]-7-undecene (DBU), ε-caprolactum, the following compound 1, the following compound 2, the following compound 3, 1,4-diazabicyclo[2.2.2]octane (DABCO), tetrahydrofurfurylamine, N-(2-aminoethyl)piperazine, hydroxyethyl piperazine, piperazine, 2-methylpiperazine, trans-2,5-dimethylpiperazine, cis-2,6-dimethylpiperazine, 2-piperidinemethanol, cyclohexylamine, and 1,5-diazabicyclo[4,3,0]-5-nonene.

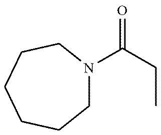

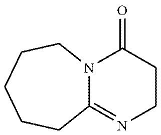 [SMILES: O=C1CCN=C2CCCCCN12]

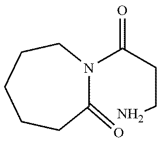 [SMILES: NCCC(=O)N1CCCCCC1=O]

Examples of the aliphatic amine compound include alkylamine, dialkylamine, and trialkylamine.

Trialkylamine is a tertiary amino group-containing compound formed by the substitution of a nitrogen atom with three alkyl groups.

Examples of the trialkylamine include trimethylamine, triethylamine, tripropylamine, tributylamine, dimethylethylamine, dimethylpropylamine, dimethylbutylamine, diethylmethylamine, diethylpropylamine, diethylbutylamine, dipropylmethylamine, dipropylethylamine, dipropylbutylamine, dibutylmethylamine, dibutylethylamine, and dibutylpropylamine.

As the trialkylamine, trimethylamine, diethylmethylamine, triethylamine, or tributylamine is preferable, and trimethylamine is more preferable.

Among amine compounds, a compound having one or more hydroxyalkyl groups in the molecule is alkanolamine.

The alkanolamine may have any of a primary amino group, a secondary amino group, and a tertiary amino group, and preferably has a primary amino group.

Examples of the alkanolamine include monoethanolamine (MEA), diethanolamine (DEA), triethanolamine (TEA), diethylene glycol amine (DEGA), trishydroxymethylaminomethane (Tris), 2-amino-2-methyl-1-propanul (AMP), 2-amino-2-methyl-1,3-dipropanol (AMPD), 2-amino-2-ethyl-1,3-dipropanol (AEPD), 2-(methylamino)-2-methyl-1-propanol (N-MAMP), 2-(aminoethoxy)ethanol (AEE), and N-(2-aminoethyl)ethanolamine (AEEA). Among these, AEE or AEEA is preferable.

The hydroxyamine compound is at least one compound selected from the group consisting of hydroxyamine (NH₂OH), a hydroxyamine derivative, and a salt of these.

The hydroxyamine compound has a function of facilitating the decomposition and solubilization of residues and removing residues such as etching residues and ashing residues.

Examples of the hydroxyamine derivative include O-methylhydroxyamine, O-ethylhydroxyamine, N-methylhydroxyamine, N,N-dimethylhydroxyamine, N,O-dimethylhydroxyamine, N-ethylhydroxyamine, N,N-diethylhydroxyamine, N,O-diethylhydroxyamine, O,N,N-trimethylhydroxyamine, N,N-dicarboxyethylhydroxyamine, and N,N-disulfoethylhydroxyamine.

Examples of salts of the hydroxyamine and the hydroxyamine derivative include an inorganic acid salt and an organic acid salt. Among these, an inorganic acid salt formed by the bonding of a non-metal atom of Cl, S, N, or P to a hydrogen atom is preferable, and a salt of any acid among hydrochloric acid, sulfuric acid, and nitric acid is more preferable.

As the inorganic acid salt of the hydroxyamine and the hydroxyamine derivative, hydroxyamine nitrate, hydroxyamine sulfate, hydroxyamine hydrochloride, hydroxyamine phosphate, N,N-diethylhydroxyamine sulfate, N,N-diethylhydroxyamine nitrate, or mixtures of these are preferable.

Examples of the organic acid salt of the hydroxyamine and the hydroxyamine derivative include hydroxyammonium citrate, hydroxyammonium oxalate, and hydroxyammonium fluoride. Among these, hydroxyamine is preferable.

The content of the basic compound with respect to the total mass of the chemical liquid is preferably 0.01% to 30% by mass, and more preferably 0.1% to 20% by mass.

Examples of the inorganic base include alkali metal hydroxides such as sodium hydroxide and potassium hydroxide, alkaline earth metal hydroxides, and ammonia and a salt thereof.

As the basic compound, in view of few metal residues after use, economics, stability of the composition, and the like, a quaternary ammonium hydroxide is preferable, TMAH or TEAH is more preferable, and TEAH is even more preferable.

### Acidic Compound

The acidic compound is an acidic compound that exhibits acidity (pH of less than 7.0) in an aqueous solution.

The acidic compound is a compound different from the various components described above.

Examples of the acidic compound include an inorganic acid, an organic acid, and a salt of these.

Examples of the inorganic acid include sulfuric acid, hydrochloric acid, nitric acid, hydrofluoric acid, perchloric acid, and a salt of these. Among these, sulfuric acid, hydrochloric acid, or nitric acid is preferable, and nitric acid, sulfuric acid, or hydrochloric acid is more preferable.

Examples of organic acid include sulfonic acid and a salt thereof.

Examples of the sulfonic acid include methanesulfonic acid (MSA), benzenesulfonic acid, p-toluenesulfonic acid (tosylic acid), and a salt of these.

As the acidic compound, sulfuric acid, hydrochloric acid, nitric acid, sulfonic acid, or a salt of these is preferable, and sulfuric acid, hydrochloride, methanesulfonic acid, or p-toluenesulfonic acid is more preferable.

The content of the pH adjuster with respect to the total mass of the chemical liquid is preferably 0.1% by mass or more, and more preferably 0.5% by mass or more. The upper limit of the content of the pH adjuster is preferably 20.0% by mass or less with respect to the total mass of the chemical liquid.

### Surfactant

The chemical liquid may contain a surfactant.

The surfactant is a compound different from the various components described above.

Examples of the surfactant include a compound having a hydrophilic group and a hydrophobic group in the molecule. Specific examples thereof include an anionic surfactant, a cationic surfactant, and a nonionic surfactant.

Examples of the hydrophobic group contained in the surfactant include an aliphatic hydrocarbon group, an aromatic hydrocarbon group, and a group obtained by combining these.

In a case where the hydrophobic group has an aromatic hydrocarbon group, the number of carbon atoms in the aromatic hydrocarbon group is preferably 6 or more, and more preferably 10 or more. The upper limit of the number of carbon atoms is preferably 24 or less, and more preferably 20 or less.

In a case where the hydrophobic group has only an aliphatic hydrocarbon group, the number of carbon atoms in the aliphatic hydrocarbon group is preferably 8 or more, and more preferably 10 or more. The upper limit of the number of carbon atoms is preferably 24 or less, and more preferably 20 or less.

Examples of the anionic surfactant include an anionic surfactant having at least one group selected from the group consisting of a sulfonic acid group, a sulfuric acid ester group, and a phosphonic acid group in the molecule.

Examples of the anionic surfactant having a sulfonic acid group include alkylsulfonic acid, alkylbenzenesulfonic acid, alkylnaphthalenesulfonic acid, alkyldiphenylether sulfonic acid, fatty acid amide sulfonic acid, and a salt of these.

Examples of the salt of the anionic surfactant include an ammonium salt, a sodium salt, a potassium salt, and a tetramethylammonium salt.

Examples of the cationic surfactant include a compound having a cationic hydrophilic group and the aforementioned hydrophobic group. Specifically, examples of the cationic surfactant include a quaternary ammonium salt-based surfactant and an alkyl pyridium-based surfactant.

The content of the surfactant with respect to the total mass of the chemical liquid is preferably 0.01% by mass or more, and more preferably 0.03% by mass or more. In view of suppressing foaming of the chemical liquid, the upper limit of the content of the surfactant with respect to the total mass of the chemical liquid is preferably 10% by mass or less, and more preferably 5% by mass or less.

### Other Organic Solvents

The chemical liquid may contain other organic solvents in addition to the polar aprotic solvent.

Examples of the other organic solvents include a hydrophilic organic solvent. The other organic solvents, an alcohol-based solvent is preferable. “Hydrophilic organic solvent” means an organic solvent that dissolves in an amount of 0.1 g or more in 100 g of water under the condition of 25° C.

As the hydrophilic organic solvent, an organic solvent that can be uniformly mixed with water at any mixing ratio is preferable.

Examples of the alcohol-based solvent include an alkanediol, an alkoxy alcohol, a saturated aliphatic monohydric alcohol, an unsaturated non-aromatic monohydric alcohol, and a low-molecular-weight alcohol having a ring structure.

Examples of the alkanediol include glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, and pinacol.

Examples of the alkoxy alcohol include 3-methoxy-3-methyl-1-butanol, 3-methoxy-1-butanol, and 1-methoxy-2-butanol.

Examples of the saturated aliphatic monohydric alcohol include methanol, ethanol, n-propyl alcohol, isopropanol, 1-butanol, 2-butanol, isobutyl alcohol, tert-butyl alcohol, 2-pentanol, t-pentyl alcohol, and 1-hexanol.

Examples of the unsaturated non-aromatic monohydric alcohol include allyl alcohol, propargyl alcohol, 2-butenyl alcohol, 3-butenyl alcohol, and 4-penten-2-ol.

Examples of low-molecular-weight alcohol having a ring structure include tetrahydrofurfuryl alcohol, furfuryl alcohol, and 1,3-cyclopentanediol.

The content of the other organic solvents with respect to the total mass of the chemical liquid is preferably 0.001% to 10% by mass, and more preferably 0.01% to 3% by mass.

### Physical Characteristics of Chemical Liquid

### pH

The pH of the chemical liquid is preferably 7 or less, more preferably 3 or less, and even more preferably 2 or less. The lower limit of the pH is preferably 0 or more.

The pH of the chemical liquid is a value obtained by measuring pH at a liquid temperature of 25° C. by using a known pH meter.

### Metal Content

The content (measured as ion concentration) of all the metals (metal elements of Fe, Co, Na, Cu, Mg, Mn, Li, Al, Cr, Ni, Zn, Sn, and Ag) contained as impurities in the chemical liquid is preferably 5 ppm by mass or less, and more preferably 1 ppm by mass or less. The manufacturing of a state-of-the-art semiconductor element presupposes the necessity for a chemical liquid with higher purity. Therefore, the metal content is even more preferably a value less than 1 ppm by mass, that is, a value in an order of ppb by mass or less, particularly preferably 100 ppb by mass or less, and most preferably less than 10 ppb by mass. The lower limit of the metal content is preferably 0 ppb by mass.

As a method of reducing the metal content, for example, a purification treatment such as distillation or filtration using an ion exchange resin or a filter is performed at the stage of raw materials to be used for manufacturing the chemical liquid or at the stage following the manufacturing of the chemical liquid. Furthermore, the filtering step that will be described later may be performed.

Examples of other methods of reducing the metal content include using a container that is unlikely to cause the elution of impurities which will be described later, as a container for accommodating the raw materials or the manufactured chemical liquid. Examples of the method of reducing the metal content also include lining the interior wall of a pipe with a fluororesin so that metal components are not eluted from the pipe and the like during the manufacturing of the chemical liquid.

### Coarse Particles

Although the chemical liquid may contain coarse particles, it is preferable that the content of the coarse particles be low.

The coarse particles are preferably different from the abrasive particles.

The coarse particles mean particles having a diameter (particle size) of 0.03 µm or more in a case where the shape of the particles is regarded as a sphere.

As for the content of the coarse particles in the chemical liquid, the number of particles having a particle size of 0.1 µm or more per 1 mL of the chemical liquid is preferably 10,000 or less, and more preferably 5,000 or less. The lower limit of the number of such particles per 1 mL of the chemical liquid is preferably 0 or more, and more preferably 0.01 or more.

The coarse particles contained in the chemical liquid are the particles such as dirt, dust, organic solids, and inorganic solids incorporated into the raw materials as impurities and the particles such as dirt, dust, organic solids, and inorganic solids mixed in as impurities in the process of preparing the chemical liquid that are remain as particles in the chemical liquid to the end without being dissolved.

The content of the coarse particles present in the chemical liquid is measured in a liquid phase by using a commercially available measuring device for a light scattering-type liquid-borne particle measuring method employing a laser as a light source.

Examples of the method of removing coarse particles include a purification treatment such as filtering that will be described later.

### Manufacturing Method of Chemical Liquid

As the manufacturing method of the chemical liquid, for example, known manufacturing methods can be used.

It is preferable that the manufacturing method of the chemical liquid have a chemical liquid preparation step.

### Chemical Liquid Preparation Step

Examples of the chemical liquid preparation step include a method of preparing phosphoric acid or a salt thereof, a polar aprotic solvent, water, and a specific compound and mixing together these components to prepare a chemical liquid. In the chemical liquid preparation step, the order in which various components are mixed together is not particularly limited. The various components may be mixed together in a batch or in divided portions.

### Filtering Step

In view of making it possible to remove foreign substances, coarse particles, and the like from the chemical liquid, the manufacturing method of the chemical liquid may have a filtering step of filtering the chemical liquid.

Examples of the filtering method include known filtering methods. Among these, filtering using a filter is preferable.

Examples of the filter used for filtering include known filters used for filtering.

Examples of materials constituting the filter include a fluororesin such as polytetrafluoroethylene (PTFE), a polyamide resin such as nylon, and a polyolefin resin such as polyethylene and polypropylene (PP) (including high-density and ultra-high-molecular-weight polyolefin resins). Among these, a polyamide resin, PTFE, or polypropylene (including high-density polypropylene) is preferable.

In a case where a filter composed of the above material is used, the foreign substances having high polarity that are likely to cause defects can be more effectively removed from the chemical liquid.

The pore diameter of the filter is preferably 0.001 to 1.0 µm, more preferably 0.02 to 0.5 µm, and even more preferably 0.01 to 0.1 µm. In a case where the pore diameter of the filter is within the above range, it is possible to remove fine foreign substances from the chemical liquid while suppressing filter clogging.

Filtering may be performed once or twice or more, and one kind of filter or two or more kinds of filters may be used.

In a case where filtering is performed twice or more by combining a first filter and a second filter different from the first filter, the filters may be the same as or different from each other. It is preferable that the filters be different from each other. It is preferable that at least one of the pore diameter or the constituent material vary between the first filter and the second filter.

The pore diameter for the second filtering and the subsequent filtering is preferably the same as or smaller than the pore diameter for the first filtering. As the pore diameter, the nominal value of the filter manufacturer can be used.

Examples of the filter include P-NYLON FILTER made of polyamide (pore diameter: 0.02 µm, critical surface tension: 77 mN/m, manufactured by Nihon Pall Ltd.), PE·CLEAN FILTER made of high-density polyethylene (pore diameter: 0.02 µm, manufactured by Nihon Pall Ltd.), and PE·CLEAN FILTER made of high-density polyethylene (pore diameter: 0.01 µm, manufactured by Nihon Pall Ltd.).

Examples of the filter include those described in paragraphs “0154” to “0162” WO2021/049208A, and what are described in these paragraphs are incorporated into the present specification.

### Electricity Removing Step

The manufacturing method of the chemical liquid may include an electricity removing step of removing electricity of the chemical liquid.

Examples of the electricity removing method include known methods such as a method of bringing a substance to be purified into contact with a conductive material.

The contact time for which the substance to be purified is brought into contact with a conductive material is preferably 0.001 to 60 seconds, more preferably 0.001 to 1 second, and even more preferably 0.01 to 0.1 seconds.

Examples of the conductive material include stainless steel, gold, platinum, diamond, and glassy carbon.

Examples of the method of bringing the substance to be purified into contact with a conductive material include a method of disposing a grounded mesh consisting of a conductive material in the interior of a pipe line and passing the substance to be purified through the mesh, and the like.

Examples of the electricity removing step include the step described in paragraph “0120” of WO2021/052186A, and what are described in the paragraph are incorporated into the present specification.

It is preferable that each step in the manufacturing method of the chemical liquid be performed in a clean room.

It is preferable that the clean room meets the 14644-1 clean room standard. The clean room preferably meets any of International Organization for Standardization (ISO) class 1, ISO class 2, ISO class 3, and ISO class 4, more preferably meets any of ISO class 1 and ISO class 2, and even more preferably meets ISO class 1.

### Container

As a container for accommodating the chemical liquid, for example, a known container can be used.

It is preferable to use a container for semiconductors which has a high internal cleanliness and is unlikely to cause elution of impurities.

Examples of the container include the “CLEAN BOTTLE” series (manufactured by Aicello Chemical Co., Ltd.) and “PURE BOTTLE” (manufactured by KODAMA PLASTICS Co., Ltd.). In view of preventing intermixing of impurities, a multilayered container that has a 6-layer structure consisting of 6 kinds of resins for the interior wall of the container or a multilayered container that has a 7-layer structure consisting of 7 kinds of resins for the interior wall of the container is preferable.

Examples of the multilayered container include the containers described in JP2015-123351A, and what are described in the document are incorporated into the present specification.

Examples of materials of the interior wall of the container include at least one first resin selected from the group consisting of a polyethylene resin, a polypropylene resin, and a polyethylene-polypropylene resin, a second resin different from the first resin, and a metal such as stainless steel, HASTELLOY, INCONEL, or MONEL. Furthermore, the interior wall of the container is preferably formed of or coated with the above materials.

As the second resin, a fluorine-based resin (perfluororesin) is preferable.

In a case where the fluorine-based resin is used, it is possible to suppress the elution of an ethylene or propylene oligomer.

Examples of the aforementioned container include a FluoroPure PFA composite drum (manufactured by Entegris, Inc.) and the containers described on page 4 of JP1991-502677A (JP-H03-502677A), page 3 of WO2004/016526A, and pages 9 and 16 of WO99/046309A.

As the Interior wall of the container, in addition to the aforementioned fluorine-based resin, quartz and a metal material finished up with electropolishing (electropolished metal material) are also preferable.

As the metal material used for the electropolished metal material, a metal material is preferable which contains at least one element selected from the group consisting of chromium (Cr) and nickel (Ni) and in which the content of Cr and Ni is more than 25% by mass with respect to the total mass of the metal material.

Examples of the metal material include stainless steel and a Ni-Cr alloy.

Examples of the metal material include the materials described in paragraphs “0075” to “0077” of WO2020/040042A, and what are described in the paragraphs are incorporated into the present specification.

Examples of the method of electropolishing the metal material include known methods. Specifically, examples thereof include the methods described in paragraphs “0011” to “0014” of JP2015-227501A and in paragraphs “0036” to “0042” of JP2008-264929A, and what are described in these paragraphs are incorporated into the present specification.

Presumably, in a case where the metal material is electropolished, the chromium content in a passive layer on the surface thereof may become higher than the chromium content in the parent phase.

Presumably, therefore, metal elements are unlikely to be discharged into the chemical liquid from the interior wall coated with the electropolished metal material, which may make it possible to obtain a chemical liquid in which the content of a specific metal element is reduced.

It is preferable that the metal material have undergone buffing.

Examples of the buffing method include known methods.

The size of abrasive grains used for finishing the buffing is preferably # 400 or less because such grains make it easy to further reduce the surface asperity of the metal material. The buffing is preferably performed before the electropolishing.

One of the multistage buffing carried out by changing the size or the like of abrasive grains, acid pickling, magnetorheological finishing or a combination of two or more of these be performed on the metal material.

It is preferable that the container be cleaned out before being filled with the chemical liquid.

The liquid to be used for cleaning can be appropriately selected depending on the use, and is preferably a liquid containing at least one of the aforementioned chemical liquid or the component added to the chemical liquid.

In view of preventing changes in the components of the chemical liquid during storage, the container may be cleaned out by purging with an inert gas (such as nitrogen or argon) having a purity of 99.99995% by volume or higher. Particularly, a gas with a low moisture content is preferable. Furthermore, the transport and storage of the container accommodating the chemical liquid may be performed at a normal temperature or at a temperature under control. Especially, in view of preventing deterioration, it is preferable to control the temperature in a range of -20 to 20° C.

### Use

The chemical liquid is preferably used for semiconductor devices, and more preferably used as an etchant.

“For semiconductor devices” means that the chemical liquid is used in the manufacturing of semiconductor devices.

The chemical liquid can also be used in steps for manufacturing a semiconductor device. For example, the chemical liquid can be used to treat a transition metal-containing substance, an insulating film, a resist film, an anti-reflection film, etching residues, ashing residues, and the like present on a substrate. The chemical liquid may also be used for treating a substrate having undergone chemical mechanical polishing.

### Object to Be Treated

The chemical liquid is preferably used to remove an Al oxide. The Al oxide is disposed on a substrate in many cases.

“On a substrate” includes all of the front and back surfaces, the side surfaces, and the inside of the grooves of the substrate. Furthermore, “Al oxide on A substrate” includes an Al oxide directly disposed on a surface of the substrate and an Al oxide disposed on the substrate via another layer.

Examples of the object to be treated include an object to be treated including an Al oxide and a Ga oxide. More specifically, examples thereof include an object to be treated including a substrate, an Al oxide disposed on the substrate, and a Ga oxide disposed on the substrate. As the object to be treated, an object to be treated is preferable which includes a substrate, an Al oxide disposed on the substrate, a Ga oxide disposed on the substrate, and a metal oxide that is disposed on the substrate and contains Hf on the substrate (hereinafter, the metal oxide will be also called “Hf oxide”). Examples of the Hf oxide include HfO₂.

The Al oxide may be an oxide containing Al (Al atoms) and may contain other metals.

The content of Al atoms in the Al oxide with respect to the total mass of the Al oxide is preferably 10% to 70% by mass, and more preferably 20% to 60% by mass.

The Ga oxide may be an oxide containing Ga (Ga atoms), and may contain other metals.

The content of Ga atoms in the Ga oxide with respect to the total mass of the Ga oxide is preferably 10% to 70% by mass, and more preferably 20% to 60% by mass.

The Hf oxide may be an oxide containing Hf (Hf atoms), and may contain other metals.

The content of Hf atoms in the Hf oxide with respect to the total mass of the Hf oxide is preferably 5% to 65% by mass, and more preferably 15% to 55% by mass.

As the substrate, a semiconductor substrate is preferable.

Examples of the semiconductor substrate include a semiconductor wafer, a glass substrate for a photomask, a glass substrate for liquid crystal display, a glass substrate for plasma display, a substrate for field emission display (FED), a substrate for an optical disk, a substrate for a magnetic disk, and a substrate for a magneto-optical disk.

Examples of materials constituting the semiconductor substrate include silicon, silicon germanium, a Group III-V compound such as GaAs, and a combination of these.

Examples of uses of the object to be treated include dynamic random access memory (DRAM), ferroelectric random access memory (FRAM, registered trademark), magnetoresistive random access memory (MRAM), phase change random access memory (PRAM), a logic circuit, and a processor.

The Al oxide on a substrate may be, for example, any of an Al oxide disposed in the form of a film, an Al oxide disposed in the form of a wiring line, and an Al oxide disposed in the form of particles.

The Ga oxide on a substrate and the Hf oxide on a substrate may be, for example, any of a Ga oxide and a Hf oxide disposed in the form of a film, a Ga oxide and a Hf oxide disposed in the form of a wiring line, and a Ga oxide and a Hf oxide disposed in the form of particles.

In a case where the Al oxide is in the form of a film, the thickness of the Al oxide film is preferably 200 nm or less, more preferably 100 nm or less, and even more preferably 50 nm or less. The lower limit of the thickness of the Al oxide film is preferably 0.1 nm or more.

In a case where the Ga oxide or the Hf oxide is in the form of a film, the thickness of the Ga oxide film or the Hf oxide film is preferably 200 nm or less, more preferably 100 nm or less, and even more preferably 50 nm or less. The lower limit of the thickness of the Ga oxide film or the Hf oxide film is preferably 0.1 nm or more.

The Al oxide, the Ga oxide, and the Hf oxide may be disposed only on one of the main surfaces of the substrate, or may be disposed on both the main surfaces of the substrate.

The object to be treated may include a layer and/or a structure as desired, in addition to the Al oxide, the Ga oxide, and the Hf oxide.

For example, a metal wire, a gate electrode, a source electrode, a drain electrode, an insulating layer, a ferromagnetic layer, and/or a non-magnetic layer may be disposed on the substrate.

The substrate may include an exposed integrated circuit structure.

Examples of the integrated circuit structure include an interconnection mechanism such as a metal wire and a dielectric material. Examples of metals and alloys used for the interconnection mechanism include aluminum, a copper-aluminum alloy, copper, titanium, tantalum, cobalt, silicon, titanium nitride, tantalum nitride, and tungsten. The substrate may include a layer of silicon oxide, silicon nitride, silicon carbide, and/or carbon-doped silicon oxide.

The size, thickness, shape, and layer structure of the substrate can be appropriately selected as desired.

### Substrate Treatment Method

The treatment method according to an embodiment of the present invention (hereinafter, also called “the present treatment method”) includes a step A of bringing an object to be treated including an Al oxide and a Ga oxide into contact with the aforementioned chemical liquid. In a case where the present treatment method is performed, the Al oxide is selectively removed.

The object to be treated by the present treatment method is as described above.

Examples of the method of bringing the object to be treated into contact with the chemical liquid include a method of immersing the object to be treated in the chemical liquid stored in a tank, a method of spraying the chemical liquid onto the object to be treated, a method of causing the chemical liquid to flow on the object to be treated, and a method as a combination of these. Among these, the method of immersing the object to be treated in the chemical liquid is preferable.

In order to further enhance the cleaning ability of the chemical liquid, a mechanical stirring method may also be used.

Examples of the mechanical stirring method include a method of circulating the chemical liquid on an object to be treated, a method of causing the chemical liquid to flow on the object to be treated or spraying the chemical liquid onto the object to be treated, and a method of stirring the chemical liquid by using ultrasonic or megasonic waves.

The treatment time of the step A can be appropriately adjusted.

The treatment time (contact time between the chemical liquid and the object to be treated) is, for example, preferably 0.25 to 10 minutes, and more preferably 0.5 to 2 minutes.

The temperature of the chemical liquid during the treatment is preferably 20° C. to 100° C., and more preferably 40° C. to 80° C.

In the step A, a treatment may be performed in which while the concentration of various components, such as phosphoric acid or a salt thereof, contained in the chemical liquid is being measured, a solvent (preferably water) is added to the chemical liquid as necessary. In a case where this treatment is performed, the concentration of various components in the chemical liquid can be stably maintained in a predetermined range.

### Other Steps

The present treatment method may have other steps in addition to the step A.

Examples of those other steps include a step of forming each structure such as a metal wire, a gate structure, a source structure, a drain structure, an insulating layer, a ferromagnetic layer and/or a non-magnetic layer (for example, layer formation, etching, chemical mechanical polishing, and modification), a step of forming resist, an exposure step and a removing step, a heat treatment step, a cleaning step, and an inspection step.

The present treatment method may be performed at any stage among the back-end process (BEOL: back end of the line), the middle process (MOL: middle of the line), and the front-end process (FEOL: front end of the line). It is preferable that the present treatment method be performed in a front-end process or a middle process.

### EXAMPLES

Hereinafter, the present invention will be more specifically described based on examples.

The materials, the amount and ratio thereof used, how to treat the materials, the treatment procedure, and the like described in the following examples can be appropriately changed as long as the gist of the present invention is maintained. Therefore, the scope of the present invention is not limited to the following examples.

### Preparation of Chemical Liquid

Chemical liquids of examples and comparative examples were prepared by mixing together various components shown in the table at the content shown in the table and the like.

All of those used as the various components shown in the table were substances classified as a semiconductor grade or classified as high-purity grade equivalent to the semiconductor grade. All of the chemical liquids of examples had a pH of 2 or less.

### Various Components

Phosphoric Acid or Salt Thereof ·Phosphoric acid

### Polar Aprotic Solvent

Sulfolane
Dimethyl sulfoxide
Tetraethylene glycol dimethyl ether
Diethylene glycol diethyl ether
Diethylene glycol butyl methyl ether

### Specific Compound

Acetic acid
Malonic acid
Succinic acid
Glutaric acid
Octanoic acid
2-Ethylhexanoic acid
Polyacrylic acid (Mw 5000, Polyacrylic acid 5,000, manufactured by FUJIFILM Wako Pure Chemical Corporation)

### Water

Ultrapure water

### Others

Phosphorous acid
Hydrofluoric acid
Citric acid

### Evaluation

### Al Oxide Etching Ability

A substrate was prepared which was obtained by forming an Al oxide layer on a commercially available silicon wafer (diameter: 12 inches) by the ALD method. From the obtained substrate, a 2 x 2 cm chip was cut, thereby preparing a test piece. The thickness of the Al oxide layer was 10 nm.

The obtained test piece was put in a container filled with the chemical liquid of each of examples and comparative examples, followed by stirring at 250 rpm. The treatment temperature was set to the temperature shown in the table, and the treatment time was set to 5 seconds, 10 seconds, 30 seconds, or 60 seconds.

By ellipsometry (using a spectroscopic ellipsometer, Vase, manufactured by J.A. Woollam Japan.), the film thickness before and after the treatment performed for each treatment time was measured, thereby calculating an etching rate (unit: Å/min). The average of etching rates at 5 spots was adopted (measurement conditions, measurement range: 1.2 to 2.5 eV, measurement angle: 70 ° or 75 °) The arithmetic mean of the obtained etching rates for each treatment time was used as the evaluation value. The etching rate of the Al oxide is preferably 1.0 Å/min or more.

### Ga Oxide Etching Ability

A substrate was prepared which was obtained by forming an Ga oxide layer on a commercially available silicon wafer (diameter: 12 inches) by the ALD method. From the obtained substrate, a 2 x 2 cm chip was cut, thereby preparing a test piece. The thickness of the Ga oxide layer was 10 nm.

By using the test piece, the Ga oxide etching ability was evaluated by the same procedure as in the evaluation of the Al oxide etching ability. The etching rate of the Ga oxide is preferably 200.0 Å/min or less.

### Hf Oxide (HfO₂) Etching Ability

A substrate was prepared which was obtained by forming an Hf oxide (HfO₂) layer on a commercially available silicon wafer (diameter: 12 inches) by the ALD method. From the obtained substrate, a 2 x 2 cm chip was cut, thereby preparing a test piece. The thickness of the Hf oxide (HfO₂) layer was 10 nm.

By using the test piece, the Hf oxide (HfO₂) etching ability was evaluated by the same procedure as in the evaluation of the Al oxide etching ability. The etching rate of the Hf oxide (HfO₂) is preferably 10.0 Å/min or less.

### Ratio of Al Oxide Etching Rate/Ga Oxide Etching Rate (Selection Ratio)

By using each of the obtained values of etching rate, the ratio of the etching rate of the Al oxide to the etching rate of the Ga oxide (Al oxide etching rate/Ga oxide etching rate) was determined, and the etching selectivity of Al oxide/Ga oxide was evaluated. The ratio of the rate is preferably 0.20 or more.

### Surface Roughness of Ga Oxide

A substrate was prepared which was obtained by forming an Ga oxide layer on a commercially available silicon wafer (diameter: 12 inches) by the ALD method. From the obtained substrate, a 2 x 2 cm chip was cut, thereby preparing a test piece. The thickness of the Ga oxide layer was 10 nm.

The obtained test piece was put in a container filled with the chemical liquid of each of examples and comparative examples, followed by stirring at 250 rpm. The treatment temperature was set to the temperature shown in the table, and the treatment time was set to 30 seconds. In a case where the Ga oxide layer of the test piece was completely dissolved in 30 seconds, the treatment time was set to 5 seconds or 10 seconds.

The obtained test piece was subjected to platinum sputtering so that platinum was deposited by 1 nm, and the surface of the test piece was observed using an SEM (field emission scanning electron microscope: S-4800, manufactured by Hitachi High-Tech Corporation.). The surface roughness of Ga oxide was evaluated according to the following evaluation standard.
A: There was no surface roughness.
B: The surface roughness was low.
C: The surface roughness was high.

### Each Description in the Tables Is as Follows

The numerical values in the columns of various components represent the content (% by mass) of various components with respect to the total mass of each chemical liquid.

The column of “Polar aprotic solvent” shows the mass ratio of the content of the polar aprotic solvent to the content of phosphoric acid (content of polar aprotic solvent/content of phosphoric acid).

TABLE 1

| Component | | Example 1 | Example 2 | Example 3 | Example 4 | Example 5 | Example 6 | Example 7 | Example 8 | Example 9 | Example 10 | Example 11 |
|---|---|---|---|---|---|---|---|---|---|---|---|---|
| Phosphoric acid | | 1.0 | 1.0 | 1.0 | 1.0 | 1.0 | 1.0 | 1.0 | 1.0 | 1.0 | 1.0 | 1.0 |
| Polar aprotic solvent | Sulfolane | 50.0 | | | 75.0 | 85.0 | 94.5 | 80.0 | 70.0 | 60.0 | 70.0 | 50.0 |
| | Dimethyl sulfoxide | | 75.0 | | | | | | | | | |
| | Tetraethylene glycol dimethyl ether | | | 75.0 | | | | | | | | |
| | Diethylene glycol diethyl ether | | | | | | | | | | | |
| | Diethylene glycol butyl methyl ether | | | | | | | | | | | |
| | Total content | 50.0 | 75.0 | 75.0 | 75.0 | 85.0 | 94.5 | 80.0 | 70.0 | 60.0 | 70.0 | 50.0 |
| Specific compound | Acetic acid | 0.5 | | | | | | 5.0 | 15.0 | 25.0 | 25.0 | 45.0 |
| | Malonic acid | | 0.2 | | | | | | | | | |
| | Succinic acid | | | 0.4 | | | | | | | | |
| | Glutaric acid | | | | 0.2 | | | | | | | |
| | Octanoic acid | | | | | | 0.5 | | | | | |
| | 2-Ethylhexanoic acid | | | | | 0.1 | | | | | | |
| | Polyacrylic acid | | | | | 0.1 | | | | | | |
| Water | | 48.5 | 23.8 | 23.6 | 23.8 | 13.8 | 4.0 | 14.0 | 14.0 | 14.0 | 40 | 4.0 |
| Others | Phosphorous acid | | | | | | | | | | | |
| | Hydrofluoric acid | | | | | | | | | | | |
| | Citric acid | | | | | | | | | | | |
| Polar aprotic solvent/phosphoric acid | | 50 | 75 | 75 | 75 | 85 | 94.5 | 80 | 70 | 60 | 70 | 50 |
| Treatment temperature (°C) | | 40 | 40 | 40 | 60 | 60 | 60 | 60 | 60 | 60 | 60 | 60 |
| Evaluation result | Al oxide etching rate (Å/min) | 30.1 | 3.1 | 2.1 | 22.4 | 17.6 | 16.3 | 15.4 | 11.3 | 7.6 | 5.5 | 4.4 |
| | Ga oxide etching rate (Å/min) | 121.0 | 6.8 | 7.4 | 50.5 | 41.6 | 44.5 | 23.3 | 10.5 | 10.0 | 4.3 | 2.9 |
| | Hf oxide etching rate (Å/min) | 0 | 0 | 0 | 0 | 0 | 0 | 0 | 0 | 0 | 0 | 0 |
| | Ratio of Al oxide etching rate/Ga oxide etching rate | 0.25 | 0.46 | 0.28 | 0.44 | 0.42 | 0.37 | 0.66 | 1.08 | 0.76 | 1.28 | 1.52 |
| | Surface roughness of Ga oxide | C | A | A | A | A | A | A | A | A | A | A |

TABLE 2

| | | | | | | | | | | | | |
|---|---|---|---|---|---|---|---|---|---|---|---|---|
| Component | | Example 12 | Example 13 | Example 14 | Example 15 | Example 16 | Example 17 | Example 18 | Example 19 | Example 20 | Example 21 | Example 22 |
| Phosphoric acid | | 1.0 | 1.0 | 1.0 | 1.0 | 1.0 | 1.0 | 1.0 | 5.0 | 4.0 | 20 | 1.0 |
| Polar aprotic solvent | Sulfolane | 85.0 | 85.0 | 85.0 | 85.0 | 85.0 | 89.0 | 83.0 | 80.0 | 80.0 | 60.0 | 80.0 |
| | Dimethyl sulfoxide | | | | | | | | | | 10.0 | |
| | Tetraethylene glycol dimethyl ether | | | | | | | | | | 10.0 | |
| | Diethylene glycol diethyl ether | | | | | | | | | | | |
| | Diethylene glycol butyl methyl ether | | | | | | | | | | | |
| | Total content | 85.0 | 85.0 | 85.0 | 85.0 | 85.0 | 89.0 | 83.0 | 80.0 | 80.0 | 80.0 | 80.0 |
| Specific compound | Acetic acid | | | | | | | | | | | |
| | Malonic acid | 50 | | | | | | 70 | 2.0 | 7.0 | 3.0 | |
| | Succinic acid | | 5.0 | | | | | | | | | |
| | Glutaric acid | | | 5.0 | | | | | | | | |
| | Octanoic acid | | | | 5.0 | | | | | | | |
| | 2-Ethylhexanoic acid | | | | | 5.0 | | | | | | |
| | Polyacrylic acid | | | | | | 1.0 | | | | | 1.0 |
| Water | | 9.0 | 9.0 | 9.0 | 9.0 | 9.0 | 9.0 | 9.0 | 13.0 | 9.0 | 15.0 | 17.9 |
| Others | Phosphorous acid | | | | | | | | | | | |
| | Hydrofluoric acid | | | | | | | | | | | 0.1 |
| | Citric acid | | | | | | | | | | | |
| Polar aprotic solvent/phosphoric acid | | 85 | 85 | 85 | 85 | 85 | 89 | 83 | 16 | 20 | 40 | 80 |
| Treatment temperature (°C) | | 60 | 60 | 60 | 60 | 60 | 60 | 60 | 60 | 60 | 60 | 60 |
| Evaluation result | Al oxide etching rate (Å/min) | 6.0 | 11.4 | 11.3 | 15.3 | 15.1 | 9.0 | 6.0 | 51.0 | 32.0 | 24.2 | 110.1 |
| | Ga oxide etching rate (Å/min) | 3.0 | 22.7 | 23.1 | 33.9 | 31.7 | 7.5 | 2.6 | 180.0 | 85.0 | 22.1 | 130.1 |
| | Hf oxide etching rate (Å/min) | 0 | 0 | 0 | 0 | 0 | 0 | 0.1 | 0.2 | 0.1 | 0.1 | 5.1 |
| | Ratio of AI oxide etching rate/Ga oxide etching rate | 2.00 | 0.50 | 0.49 | 0.45 | 0.48 | 1.20 | 2.31 | 0.28 | 0.38 | 1.10 | 0.85 |
| | Surface roughness of Ga oxide | A | A | A | A | A | A | A | C | A | A | C |

TABLE 3

| | | | | | | | | | | | |
|---|---|---|---|---|---|---|---|---|---|---|---|
| Component | | Example 23 | Example 24 | Example 25 | Example 26 | Comparative Example 1 | Comparative Example 2 | Comparative Example 3 | Comparative Example 4 | Comparative Example 5 | Comparative Example 6 |
| Phosphoric acid | | 1.0 | 1.0 | 1.0 | 1.0 | 6.0 | | 1.0 | 1.0 | 1.0 | 1.0 |
| Polar aprotic solvent | Sulfolane | | | 80.0 | 80.0 | 85.0 | 85.0 | 40.0 | 97.5 | 40.0 | 85.0 |
| | Dirnethyl sulfoxide | | | | | | | | | | |
| | Tetraethylene glycol dimethyl ether | | | | | | | | | | |
| | Diethylene glycol diethyl ether | 80.0 | | | | | | | | | |
| | Diethylene glycol butyl methyl ether | | 80.0 | | | | | | | | |
| | Total content | 80.0 | 80.0 | 80.0 | 80.0 | 85.0 | 85.0 | 40.0 | 97.5 | 40.0 | 85.0 |
| Specific compound | Acetic acid | | | 3.0 | | | | | | 50.0 | |
| | Malonic acid | 3.0 | | 3.0 | 3.0 | 2.0 | | 2.0 | | | |
| | Succinic acid | | 3.0 | | | | | | 1.0 | | |
| | Glutaric acid | | | | | | 2.0 | | | | |
| | Octanoic acid | | | | | | | | | | |
| | 2-Ethylhexanoic acid | | | | | | | | | | |
| | Polyacrylic acid | | | | 1.0 | | | | | | |
| Water | | 16.0 | 16.0 | 13.0 | 15.0 | 7.0 | 12.0 | 57.0 | 0.5 | 9.0 | 11.0 |
| Others | Phosphorous acid | | | | | | 1.0 | | | | |
| | Hydrofluoric acid | | | | | | | | | | |
| | Citric acid | | | | | | | | | | 3.0 |
| Polar aprotic solvent/phosphoric acid | | 80 | 80 | 80 | 80 | 14 | | 40 | 98 | 40 | 85 |
| Treatment temperature (°C) | | 60 | 60 | 60 | 60 | 60 | 60 | 60 | 60 | 60 | 60 |
| Evaluation result | Al oxide etching rate (Å/min) | 3.3 | 4.1 | 12.3 | 6.8 | 71.0 | 0 | 23.1 | 0.9 | 0.9 | 17.4 |
| | Ga oxide etching rate (Å/min) | 7.1 | 9.0 | 11.1 | 5.5 | 304.0 | 15.2 | 301.0 | 0.7 | 1.1 | 140.1 |
| | Hf oxide etching rate (Å/min) | 0.1 | 0.1 | 0.1 | 0.1 | 0.1 | 0 | 0.5 | 0 | 0.1 | 0.1 |
| | Ratio of Al oxide etching rate/Ga oxide etching rate | 0.46 | 0.46 | 1.11 | 1.24 | 0.23 | 0 | 0.08 | 1.29 | 0.82 | 0.12 |
| | Surface roughness of Ga oxide | A | A | A | A | C | A | C | A | A | C |

From the results shown in the table, it has been confirmed that the chemical liquid according to the embodiment of the present invention brings about the effect of the present invention.

It has been confirmed that in a case where the content of water is 2.0% to 30.0% by mass with respect to the total mass of the chemical liquid, the etching selectivity of the Al oxide to the Ga oxide is further improved (comparison of Examples 1 to 5 and the like). Furthermore, it has been confirmed that in a case where the content of water is 2.0% to 10.0% by mass with respect to the total mass of the chemical liquid, the etching selectivity of the Al oxide to the Ga oxide is further improved (comparison of Examples 1 to 5, 7 to 11, and 19 and 20).

It has been confirmed that in a case where the specific compound includes at least one compound selected from the group consisting of malonic acid, poly(meth)acrylic acid, and a salt of these (preferably in a case where the specific compound includes malonic acid), the etching selectivity of the Al oxide to the Ga oxide is further improved (comparison of Examples 12 to 17, and the like).

It has been confirmed that in a case where the content of phosphoric acid or a salt thereof is 3.0% by mass or less with respect to the total mass of the chemical liquid, the etching selectivity of the Al oxide to the Ga oxide is further improved (comparison between Examples 18 and 20, and the like).

It has been confirmed that in a case where the etching rate of a Ga oxide is reduced, the surface roughness of the Ga oxide can be reduced (comparison of Examples 1 to 26, and the like).

What is claimed is:

1. A chemical liquid comprising:
phosphoric acid or a salt thereof;
a polar aprotic solvent;
water; and
a compound that has a carboxy group and does not have a hydroxyl group or a salt of the compound,
wherein a content of the phosphoric acid or a salt thereof is 5.0% by mass or less with respect to a total mass of the chemical liquid,
a content of the polar aprotic solvent is 50.0% by mass or more with respect to the total mass of the chemical liquid, and
a content of the water is 2.0% by mass or more and less than 50.0% by mass with respect to the total mass of the chemical liquid.

2. The chemical liquid according to claim 1,
wherein the content of the phosphoric acid or a salt thereof is 3.0% by mass or less with respect to the total mass of the chemical liquid.

3. The chemical liquid according to claim 1,
wherein the polar aprotic solvent includes at least one solvent selected from the group consisting of sulfolane, dimethyl sulfoxide, and an ether-based solvent.

4. The chemical liquid according to claim 1,
wherein the polar aprotic solvent includes sulfolane.

5. The chemical liquid according to claim 1,
wherein a mass ratio of the content of the polar aprotic solvent to the content of the phosphoric acid or a salt thereof is more than 40.

6. The chemical liquid according to claim 1,
wherein a mass ratio of the content of the polar aprotic solvent to the content of the phosphoric acid or a salt thereof is more than 80.

7. The chemical liquid according to claim 1,
wherein the content of the water is 2.0% to 30.0% by mass with respect to the total mass of the chemical liquid.

8. The chemical liquid according to claim 1,
wherein the content of the water is 2.0% to 15.0% by mass with respect to the total mass of the chemical liquid.

9. The chemical liquid according to claim 1,
wherein the content of the water is 2.0% to 10.0% by mass with respect to the total mass of the chemical liquid.

10. The chemical liquid according to claim 1,
wherein the compound that has a carboxy group and does not have a hydroxyl group or a salt of the compound includes at least one compound selected from the group consisting of a compound represented by Formula (C1) and a compound having a repeating unit represented by Formula (C2),
$${\text{Z}}^{1} - {\text{L}}^{1} - {\left({\text{Z}}^{2}\right)}_{\text{n}}$$
in Formula (C1), Z¹ represents a hydrocarbon group or a carboxy group or a salt thereof, L¹ represents a single bond or an (n + 1)-valent hydrocarbon group, Z² represents a carboxy group or a salt thereof, n represents an integer of 1 to 5, here, in a case where L¹ represents a single bond, n represents 1, 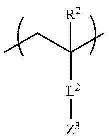
in Formula (C2), R² represents a hydrogen atom, a methyl group, or a carboxy group or a salt thereof, L² represents a single bond or a divalent linking group, and Z³ represents a carboxy group or a salt thereof.

11. The chemical liquid according to claim 1,
wherein the compound that has a carboxy group and does not have a hydroxyl group or a salt of the compound includes at least one compound selected from the group consisting of acetic acid, malonic acid, succinic acid, glutaric acid, octanoic acid, 2-ethylhexanoic acid, poly(meth)acrylic acid, and a salt of these.

12. The chemical liquid according to claim 1,
wherein the chemical liquid substantially does not contain a fluoride.

13. The chemical liquid according to claim 1,
wherein the chemical liquid substantially does not contain hydrogen peroxide.

14. The chemical liquid according to claim 1,
wherein the chemical liquid substantially does not contain abrasive particles.

15. The chemical liquid according to claim 1,
wherein the chemical liquid has a pH of 2 or less.

16. The chemical liquid according to claim 1,
wherein the chemical liquid is used for an object to be treated that includes an Al-containing metal oxide and a Ga-containing metal oxide.

17. The chemical liquid according to claim 1,
wherein the chemical liquid is used as an etchant.

18. A treatment method comprising:
bringing an object to be treated including an Al-containing metal oxide and a Ga-containing metal oxide into contact with the chemical liquid according to claim 1.

19. The treatment method according to claim 18,
wherein a temperature of the chemical liquid is 40° C. to 80° C.
